(19) United States
(12) Patent Application Publication
(10) Pub. No.: US 2008/0054793 A1
(43) Pub. Date: Mar. 6, 2008

(54) White light-emitting apparatus

(75) Inventors: Chih-Chieh Yang, Tu Chen City (TW); Chih-Min Lin, Tu Chen City (TW); Yi-Jung Chen, Tu Chen City (TW); Ru-Shi Liu, Taipei (TW)

Correspondence Address: BIRCH STEWART KOLASCH & BIRCH, PO BOX 747, FALLS CHURCH, VA, 22040-0747, US

(73) Assignee: Everlight Electronics Co., Ltd.

(21) Appl. No.: 11/808,863

(22) Filed: Jun. 13, 2007

Related U.S. Application Data
(60) Provisional application No. 60/840,946, filed on Aug. 30, 2006.

(51) Int. Cl. H01L 51/50

(52) U.S. Cl. 313/503

(57) ABSTRACT

A white light-emitting apparatus including a light-emitting device, a nitride fluorescent material and an oxynitride fluorescent material is provided. The light-emitting device is capable of generating a first color light having a first wavelength range. The nitride fluorescent material and the oxynitride fluorescent material cover the light-emitting device. The nitride and oxynitride fluorescent material are excited by the first color light, and further generate a second color light having a second wavelength range and a third color light having a third wavelength range, respectively. The first, second and third color lights are mixed together to generate a white light. A white light-emitting diode is also disclosed.

### CROSS-REFERENCE TO RELATED APPLICATION

This application claims the priority benefit of U.S. Provisional Application Ser. No. 60/840,946, filed Aug. 30, 2006, the full disclosures of which are incorporated herein by reference.

### BACKGROUND

1. Field of Invention

The present invention relates to a light-emitting apparatus. More particularly, the present invention relates to a white light-emitting apparatus.

2. Description of Related Art

White light-emitting diode is gradually used in various illuminating products and backlight of liquid crystal display, because it is featured by low power consumption, low driving voltage, long life time and environment-friendly characteristic.

White light emitted from a conventional light-emitting diode can be generated by mixing blue light generated from a blue light-emitting device and yellow light generated from a yellow fluorescent material. However, the color rendering property and color saturation of conventional light-emitting diode are poor. Besides, the CIE chromaticity coordinate of the white light generated from the conventional light-emitting diode operated in high current flow is seriously deviated from its original coordinate location. The disadvantages mentioned above reduce display quality of liquid crystal display and illuminating quality of illuminating product. Therefore, it is necessary to develop a white light-emitting diode having stable color display, good color rendering property and good color saturation performance in different current flows.

### SUMMARY

A white light-emitting apparatus including a light-emitting device, a nitride fluorescent material and an oxynitride fluorescent material is provided. The light-emitting device is capable of generating a first color light having a first wavelength range. The nitride fluorescent material and the oxynitride fluorescent material cover the light-emitting device. The nitride and oxynitride fluorescent material are excited by the first color light, and further generate a second color light having a second wavelength range and a third color light having a third wavelength range, respectively. The first, second and third color lights are mixed together to generate white light.

A white light-emitting diode including a light-emitting device, a nitride fluorescent material and an oxynitride fluorescent material is provided. The light-emitting device is capable of generating blue light having a first wavelength range. The nitride fluorescent material and the oxynitride fluorescent material cover the light-emitting device, and consist of cerium-activated nitride compound and europium-activated oxynitride compound respectively. The nitride and oxynitride fluorescent material separately emit red light having a second wavelength range and green light having a third wavelength range, when they are excited by blue light. The blue light, red light and green light are mixed together to generate white light.

### BRIEF DESCRIPTION OF THE DRAWINGS

These and other features, aspects, and advantages of the present invention will become better understood with regard to the following description, appended claims, and accompanying drawings where:

FIG. 1 shows a cross-sectional view of the white light-emitting apparatus according to one embodiment of the present invention.

FIG. 2 shows an emission spectrum of the white light-emitting apparatus according to one embodiment of the present invention and operated with 20 mA direct current flow.

FIG. 3 shows a change of the CIE chromaticity coordinate of light generated from the white light-emitting apparatus shown in FIG. 1 and operated with different current flows.

### DETAILED DESCRIPTION

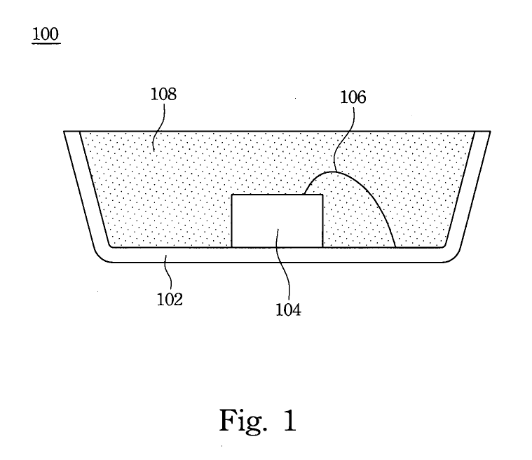

FIG. 1 shows a cross-sectional view of the white light-emitting apparatus according to one embodiment of the present invention. Referring to FIG. 1, the white light-emitting apparatus 100 includes a light-emitting device 104 and a package resin 108. The light-emitting device 104 is located on a package cup 102. The package resin 108 includes a nitride fluorescent material consisting of nitride compound and an oxynitride fluorescent material consisting of oxynitride compound. The nitride fluorescent material and the oxynitride fluorescent material are distributed in the package resin 108. Besides, the white light-emitting apparatus 100 further includes at least one conductive line 106 capable of connecting with the package cup 102 and the light-emitting device 104. The light-emitting device 104 receives an external voltage via the conductive line 106 to radiate light.

The white light-emitting apparatus 100 given above can be a white light-emitting diode. The light-emitting device 104 is capable of generating a first color light having a first wavelength range. The nitride fluorescent material and the oxynitride fluorescent material can be excited by the first color light to generate a second color light having a second wavelength range, and a third color light having a third wavelength range respectively. The first, second and third color lights can be mixed together to generate a white light.

The first color light can be blue light, and the first wavelength range is about 360˜480 nm. The second color light can be red light, and the second wavelength range is about 560˜760 nm. The third color light can be green light, and the third wavelength range is about 490˜660 nm.

The light-emitting device 104 given above can be a semiconductor device. The semiconductor device can be a composite compound consisting of group III-IV elements in the periodic table. The nitride fluorescent material described above can be a cerium-activated nitride compound such as CaₓSi_{y}N₃:Ce (0<(x,y)<4) or CaSiN₂:Ce (exciting wavelength is about 300˜500 nm). The oxynitride fluorescent material can be an europium-activated oxynitride compound such as Sr₂₋₂ₓSiO_{4-y}N_{y}:Eu (0<x<1, 0<y<4) or SrSi₂O₂N₂:Eu (exciting wavelength is about 350˜480 nm).

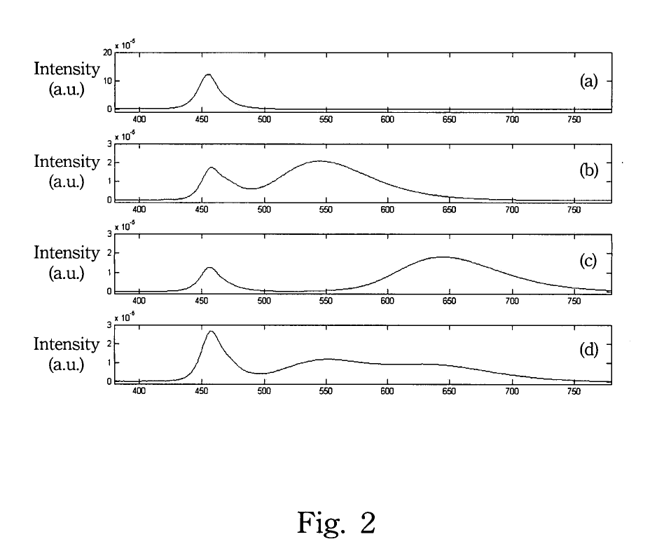

Referring to FIG. 2, an emission spectrum of the white light-emitting apparatus 100 (in FIG. 1) operated with 20 mA (milliampere) direct current flow is shown. Part (a) of FIG. 2 shows an emission spectrum of the semiconductor light-emitting device consisting of group III-V elements in the periodic table. The emission spectrum is a blue light spectrum and the emission wavelength thereof is about 430-480 nm.

Part (b) of FIG. 2 shows an emission spectrum of the foregoing oxynitride fluorescent material (SrSi₂O₂N₂:Eu) excited by blue light. The emission spectrum is a green light spectrum and the emission wavelength thereof is about 480˜660 nm. The spectrum in the range of 430˜480 nm is the emission spectrum of the blue light generated from the semiconductor light-emitting device, which is used to excite the oxynitride fluorescent material.

Part (c) of FIG. 2 shows an emission spectrum of the foregoing nitride fluorescent material (CaSiN₂:Ce) excited by blue light. The emission spectrum is a red light spectrum and the emission wavelength thereof is about 560˜780 nm. Similar to part (b), the spectrum in the range of 430˜480 nm is the emission spectrum of the blue light generated from the semiconductor light-emitting device, which is used to excite the nitride fluorescent material.

Part (d) of FIG. 2 shows a white light spectrum generated the blue, green and red light spectrum given above. The emission wavelength of the white light spectrum is about 430˜780 nm.

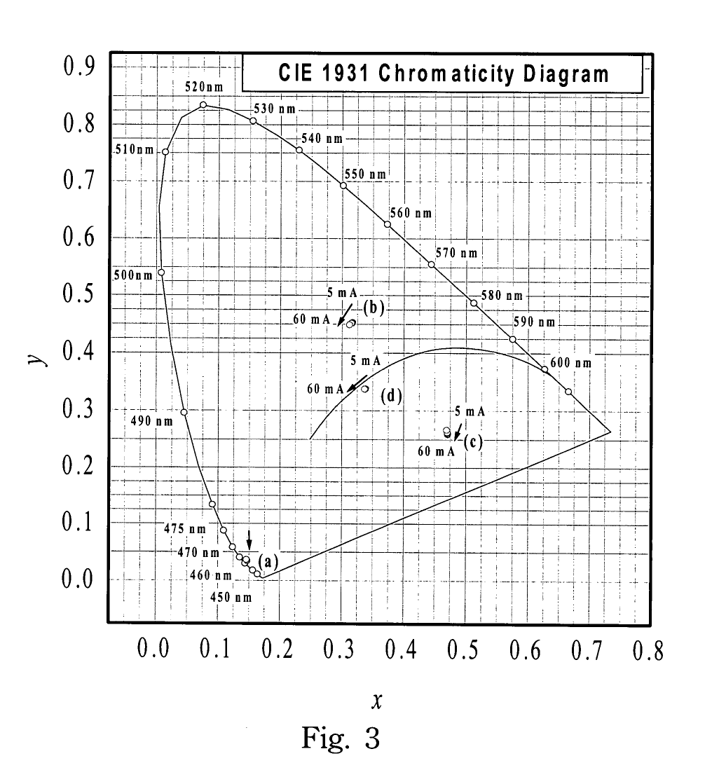

FIG. 3 shows a change of the CIE chromaticity coordinate of light generated from the white light-emitting apparatus shown in FIG. 1 and operated with different current flows. Referring to FIG. 3, symbols a, b and c represent the CIE chromaticity coordinate of blue light, green light and red light generated from the light-emitting device and fluorescent material respectively. Symbol d represents white light consisting of the mixture of blue light, green light and red light given above. The CIE chromaticity coordinate of the light generated from the white light-emitting apparatus 100 (in FIG. 1) operated with different current flows is quite stable. The white light-emitting apparatus 100 provides stable color display in different current flows, as indicated from FIG. 3.

Table 1 further shows a change of color characteristic of white light generated from the white light-emitting apparatus in FIG. 1 operated with 5˜60 mA current flow. The CIE chromaticity coordinate, color temperature and color rendering property of white light are quite stable when the current flow is increased from 5 mA to 60 mA. For example, the CRI of white light only changes about 2.1%, the color temperature change is lower than 1.5%.

TABLE 1
Color characteristic of white light generated from the white
light-emitting apparatus operated with 5~60 mA current flow.

| Current | CIE_{x,y} chromaticity | Color temperature | Color rendering |
|---|---|---|---|
| (mA) | coordinate | (K) | index (CRI) |
| 5 | (0.3383, 0.3363) | 5239 | 90.3 |
| 10 | (0.3387, 0.3368) | 5218 | 90.3 |
| 20 | (0.3391, 0.3374) | 5206 | 90.5 |
| 30 | (0.3389, 0.3373) | 5211 | 90.9 |
| 40 | (0.3384, 0.3372) | 5230 | 91.2 |
| 60 | (0.3369, 0.3367) | 5297 | 92.2 |

The white light-emitting apparatus 100 given above provides stable CIE chromaticity coordinate, color temperature and color rendering index in different current flows. Therefore, the white light-emitting apparatus thereof has a stable color display performance in different current flows. Besides, the white light-emitting apparatus 100 exhibits better color rendering property (CRI is about 90) than ordinary white light-emitting apparatus (CRI is about 80). Moreover, the color saturation of the display including white light-emitting apparatus 100 used as a backlight is 68%, 8% higher than that of conventional displays with backlight consisting of blue light emitting device and yellow color fluorescent material (about 60%).

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A white light-emitting apparatus, comprising:
a light-emitting device capable of generating a first color light having a first wavelength range;
a nitride fluorescent material covering the light-emitting device, wherein the nitride fluorescent material is excited by the first color light and further generates a second color light having a second wavelength range; and
an oxynitride fluorescent material covering the light-emitting device, wherein the oxynitride fluorescent material is excited by the first color light and further generates a third color light having a third wavelength range, and the third color light is mixed with the first color light and second color light to generate a white light.

2. The white light-emitting apparatus of claim 1, wherein the first color light is blue light.

3. The white light-emitting apparatus of claim 1, wherein the light-emitting device is a semiconductor device.

4. The white light-emitting apparatus of claim 3, wherein the semiconductor device is a composite compound consisting of group III-IV elements in the periodic table.

5. The white light-emitting apparatus of claim 1, wherein the first wavelength range is about 360˜480 nm.

6. The white light-emitting apparatus of claim 1, wherein the second color light is red light.

7. The white light-emitting apparatus of claim 1, wherein the second wavelength range is about 560˜760 nm.

8. The white light-emitting apparatus of claim 1, wherein the nitride fluorescent material is cerium-activated nitride compound.

9. The white light-emitting apparatus of claim 8, wherein the chemical formula of the nitride fluorescent material is CaSiN₂:Ce.

10. The white light-emitting apparatus of claim 9, wherein the exciting wavelength of the nitride fluorescent material is about 300˜500 nm.

11. The white light-emitting apparatus of claim 8, wherein the chemical formula of the nitride fluorescent material is CaₓSi_{y}N₃:Ce, and 0<(x, y)<4.

12. The white light-emitting apparatus of claim 1, wherein the third color light is green light.

13. The white light-emitting apparatus of claim 1, wherein the third wavelength range is about 490˜660 nm.

14. The white light-emitting apparatus of claim 1, wherein the oxynitride fluorescent material is an europium-activated oxynitride compound.

15. The white light-emitting apparatus of claim 14, wherein the chemical formula of the oxynitride fluorescent material is SrSi₂O₂N₂:Eu.

16. The white light-emitting apparatus of claim 15, wherein the exciting wavelength of the oxynitride fluorescent material is about 350˜480 nm.

17. The white light-emitting apparatus of claim 14, wherein the chemical formula of the oxynitride fluorescent material is Sr₂₋₂ₓSiO_{4-y}N_{y}:Eu, and 0<x<1, 0<y<4.

18. A white light-emitting diode, comprising:
a light-emitting device capable of generating blue light having a first wavelength range;
a nitride fluorescent material covering the light-emitting device, wherein the nitride fluorescent material is a cerium-activated nitride compound and excited by blue light to generate red light having a second wavelength range; and
an oxynitride fluorescent material covering the light-emitting device, wherein the oxynitride fluorescent material is an europium-activated oxynitride compound and excited by blue light to generate green light having a third wavelength range, and green light is mixed with red light and blue light to generate white light.

19. The white light-emitting diode of claim 18, wherein the chemical formula of the nitride fluorescent material is CaSiN₂:Ce.

20. The white light-emitting diode of claim 18, wherein the chemical formula of the oxynitride fluorescent material is SrSi₂O₂N₂:Eu.
